(19) United States
(12) Patent Application Publication
(10) Pub. No.: US 2012/0229990 A1
(43) Pub. Date: Sep. 13, 2012

(54) MULTILAYER PRINTED WIRING BOARD AND METHOD FOR MANUFACTURING MULTILAYER PRINTED WIRING BOARD

(75) Inventors: Takema ADACHI, Ogaki-shi (JP); Liyi Chen, Ogaki-shi (JP)

(73) Assignee: IBIDEN CO., LTD., Ogaki-shi (JP)

(21) Appl. No.: 13/404,149

(22) Filed: Feb. 24, 2012

Related U.S. Application Data
(60) Provisional application No. 61/450,336, filed on Mar. 8, 2011.

(51) Int. Cl. H05K 1/00; B32B 38/00; H05K 7/00; H05K 3/46

(52) U.S. Cl. 361/748; 427/96.9; 156/278; 174/258

(57) ABSTRACT

A printed wiring board has a metal layer, a resin structure having a first resin layer portion formed on a first surface of the metal layer, a second resin layer portion formed on a second surface of the metal layer, and a filler resin portion filling an opening portion of the metal layer, a first circuit formed on the first resin portion, a second circuit formed on the second resin portion, and a through-hole conductor formed through the first resin, filler resin and second resin portions and connecting the first and second circuits. The through-hole conductor has a first portion narrowing from the first circuit toward the second resin portion and a second portion narrowing from the second circuit toward the first resin portion, and the first portion is connected to the second portion at a connected position shifted from the middle point of the thickness of the metal layer.

### CROSS-REFERENCE TO RELATED APPLICATIONS

The present application is based on and claims the benefit of priority to U.S. Application No. 61/450,336, filed Mar. 8, 2011, the entire contents of which are incorporated herein by reference.

### BACKGROUND OF THE INVENTION

1. Field of the Invention

The present invention relates to a printed wiring board having the following: a core substrate having a metal layer and resin insulation layers sandwiching the metal layer; conductive circuits formed on upper and lower surfaces of the core substrate; and a through-hole conductor penetrating through the core substrate and connecting the conductive circuits on the upper and lower surfaces of the core substrate. The present invention also relates to a method for manufacturing such a printed wiring board.

2. Discussion of the Background

Japanese Laid-Open Patent Publication 2003-304063 describes a method for manufacturing a metal core substrate. In the manufacturing method, a penetrating hole is formed in a metal layer, insulation layers are laminated on upper and lower surfaces of the metal layer, a through hole that goes through the penetrating hole is formed in the metal layer and the insulation layers formed on the upper and lower surfaces of the metal layer, and a conductive layer (through-hole conductor) is formed on the inner wall of the through hole. The contents of this publication are incorporated herein by reference in their entirety.

### SUMMARY OF THE INVENTION

According to one aspect of the present invention, a printed wiring board includes a metal layer having an opening portion, a resin structure having a first resin layer portion formed on a first surface of the metal layer, a second resin layer portion formed on a second surface of the metal layer on the opposite side of the first surface, and a filler resin portion filling the opening portion of the metal layer, a first conductive circuit formed on the first resin insulation layer portion, a second conductive circuit formed on the second resin insulation layer portion, and a through-hole conductor formed through the first resin insulation layer portion, the filler resin portion and the second resin insulation layer portion and connecting the first conductive circuit and the second conductive circuit. The through-hole conductor has a first portion narrowing from the first conductive circuit toward the second resin insulation layer portion and a second portion narrowing from the second conductive circuit toward the first resin insulation layer portion, and the first portion of the through-hole conductor is connected to the second portion of the through-hole conductor at a connected position shifted from a middle point of a thickness of the metal layer.

According to another aspect of the present invention, a method for manufacturing a printed wiring board includes forming an opening through a metal layer, forming on a first surface of the metal layer a first resin insulation layer, forming on a second surface of the metal layer on the opposite side of the first surface a second resin insulation layer, forming a penetrating hole penetrating through the opening of the metal layer such that the penetrating hole penetrates through the first resin insulation layer and the second resin insulation layer, forming a first conductive circuit on the first resin insulation layer, forming a second conductive circuit on the second resin insulation layer, and forming in the penetrating hole a through-hole conductor connecting the first conductive circuit and the second conductive circuit. The opening of the metal layer is filled with a filler resin derived from at least one of the first resin insulation layer and the second resin insulation layer, the forming of the penetrating hole includes forming a first opening portion in the first resin insulation layer such that the first opening portion is narrowing toward the second resin insulation layer and forming a second opening portion in the second resin insulation layer such that the second opening portion is narrowing toward the first resin insulation layer, connected to the first opening portion and forms a connected portion of the first and second opening portions shifted from a middle point of a thickness of the metal layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1(A)-(F) are views of steps showing a method for manufacturing a multilayer printed wiring board according to an embodiment of the present invention;

FIGS. 2(A)-(D) are views of steps showing a method for manufacturing a multilayer printed wiring board according to the embodiment;

FIGS. 3(A)-(D) are views of steps showing a method for manufacturing a multilayer printed wiring board according to the embodiment;

FIGS. 4(A)-(C) are views of steps showing a method for manufacturing a multilayer printed wiring board according to the embodiment;

FIGS. 5(A)-(B) are views of steps showing a method for manufacturing a multilayer printed wiring board according to the embodiment;

FIG. 6 is a cross-sectional view of a multilayer printed wiring board according to the embodiment;

FIG. 7 is a cross-sectional view showing a state in which an IC chip is mounted on the multilayer printed wiring board shown in FIG. 6;

FIGS. 8(A)-(B) are views showing an example of each dimension in a core substrate;

FIGS. 9(A), 9(B), 9(D) and 9(E) are views showing examples of the shape of a penetrating hole for a through-hole conductor;

FIG. 10(A) shows an opening of a first opening portion, and FIG. 10(B) shows an opening of a second opening portion;

FIGS. 11(A)-(D) are views of steps showing a method for manufacturing a printed wiring board according to a modified example of the embodiment; and

FIGS. 12(A)-(B) are views of steps showing a method for manufacturing a printed wiring board according to the modified example of the embodiment.

### DETAILED DESCRIPTION OF THE EMBODIMENTS

The embodiments will now be described with reference to the accompanying drawings, wherein like reference numerals designate corresponding or identical elements throughout the various drawings.

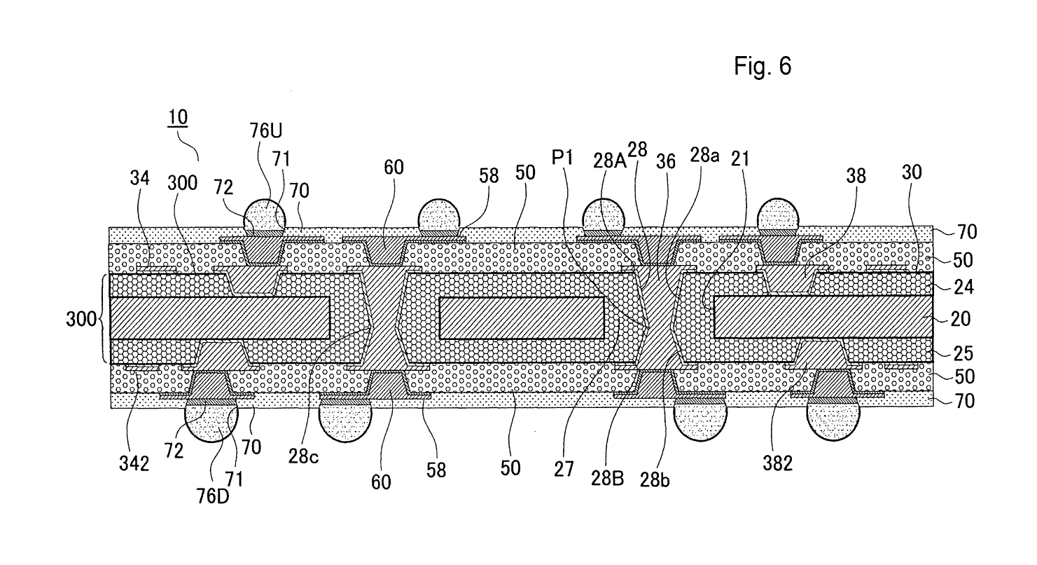

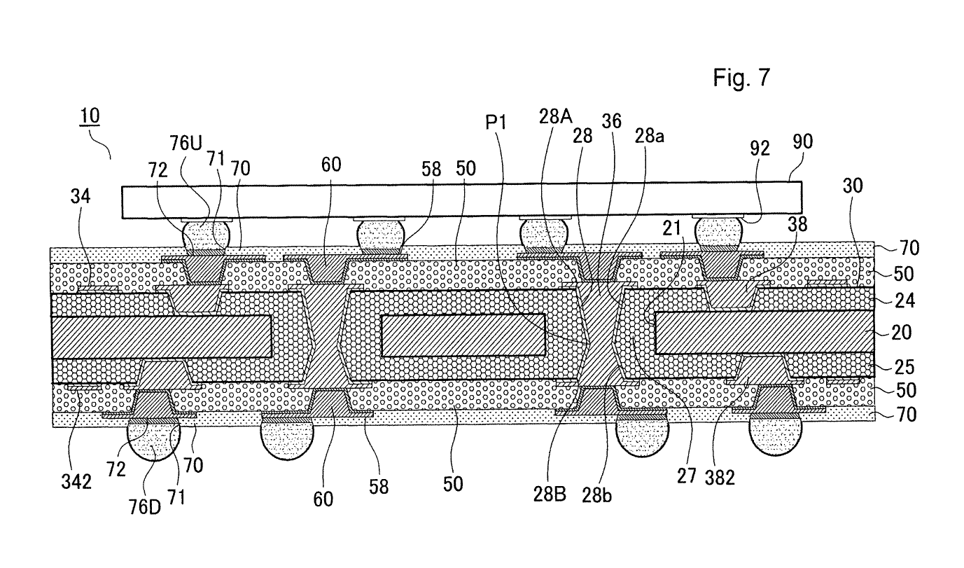

A cross-sectional view of a multilayer printed wiring board according to an embodiment of the present invention is shown in FIG. 6 and FIG. 7. FIG. 7 shows a state in which IC chip 90 is mounted on multilayer printed wiring board 10 shown in FIG. 6. IC chip 90 is mounted on multilayer printed wiring board 10 through solder bumps (76U). Multilayer printed wiring board 10 has printed wiring board 30, interlayer resin insulation layers 50 formed on both surfaces of the printed wiring board, conductive circuits 58 on interlayer resin insulation layers, and via conductors 60 connecting conductive circuits on the printed wiring board and conductive circuits on the interlayer resin insulation layers.

Printed wiring board 30 is formed with core substrate 300 and conductive circuits (34, 342) on the core substrate. Core substrate 300 has metal layer 20 which has opening 21 and a first surface and a second surface opposite the first surface, filler resin 27 filling the opening in metal layer 20, first resin insulation layer 24 formed on the first surface of the metal layer, second resin insulation layer 25 formed on the second surface of the metal layer, and through-hole conductor 36 formed in penetrating hole 28 for a through-hole conductor that penetrates through the first resin insulation layer, the filler resin and the second resin insulation layer. Metal layer 20 is sandwiched by first resin insulation layer 24, which has an upper surface and a lower surface opposite the upper surface, and by second resin insulation layer 25, which has a main surface and a secondary surface opposite the main surface. The first surface of the metal layer faces the lower surface of the first resin insulation layer. The second surface of the metal layer faces the secondary surface of the second resin insulation layer. First conductive circuit 34 is formed on the upper surface of the first resin insulation layer. Second conductive circuit 342 is formed on the main surface of the second resin insulation layer. A first conductive circuit and a second conductive circuit of printed wiring board 30 are connected by through-hole conductor 36. The first surface of the core substrate and the upper surface of the first resin insulation layer are on the same plane, and the second surface of the core substrate and the main surface of the second resin insulation layer are on the same plane.

Via conductors 60 connect conductive circuits 58 on interlayer resin insulation layers 50 with conductive circuits (34, 342) on the printed wiring board or with through-hole conductor 36. Multilayer printed wiring board 10 in FIG. 6 has one buildup layer on each side. Multilayer printed wiring board 10 in FIG. 6 has solder-resist layers 70 on buildup layers, and via conductors 60 and conductive circuits 58 in the buildup layers are exposed through openings 71 in solder-resist layers 70. Bumps (76U, 76D) are formed in the exposed portions.

Penetrating hole 28 is made up of first opening portion (28a) formed in first resin insulation layer 24 and filler resin 27 and of second opening portion (28b) formed in second resin insulation layer 25 and filler resin 27. The first opening portion and the second opening portion are connected at connected portion (connected position) (28c). The first opening portion has first opening (28A) on the first surface of the core substrate and becomes gradually narrower from the first surface of the core substrate toward the filler resin. The second opening portion has second opening (28B) on the second surface of the core substrate and becomes gradually narrower from the second surface of the core substrate toward the filler resin. Connected portion (connected position) (28c) is the position where first opening portion (28a) and second opening portion (28b) are connected.

As shown in FIG. 6, it is an option for printed wiring board 30 to have via conductor 38 which penetrates through first resin insulation layer 24 and connects metal layer 20 and conductive circuit 34. Furthermore, it is also an option for printed wiring board 30 to have via conductor 382 which penetrates through second resin insulation layer 25 and connects metal layer 20 and conductive circuit 342. Printed wiring board 30 is not always required to have via conductors (38, 382).

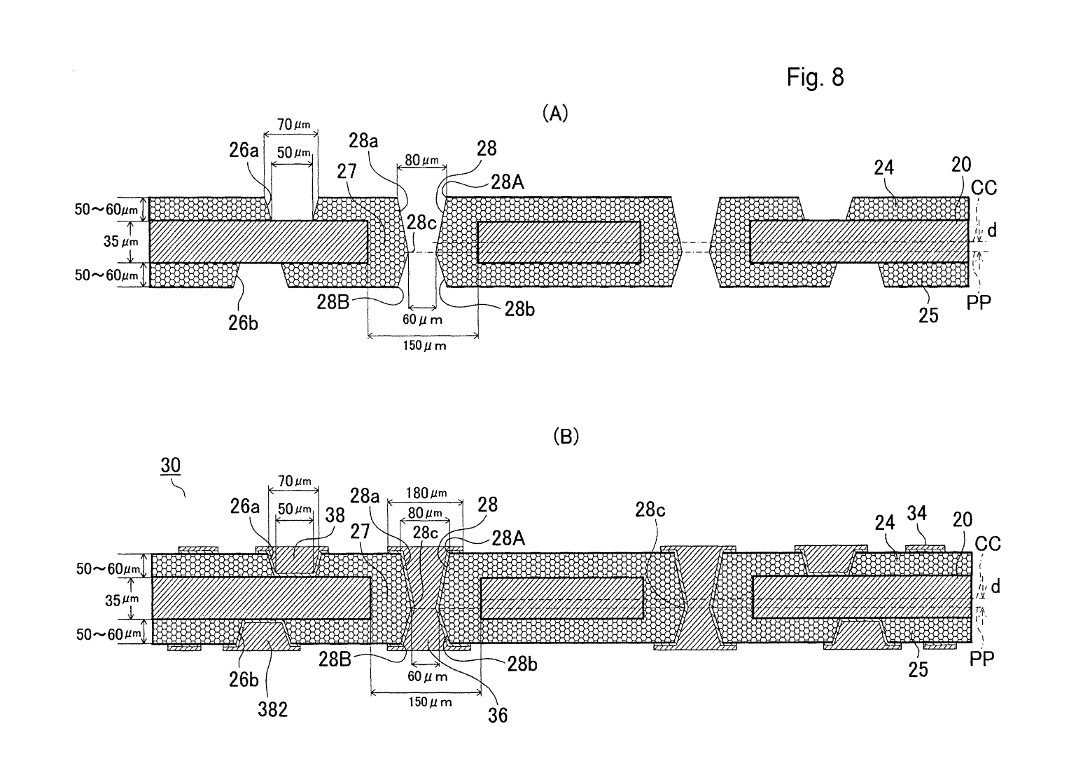

FIG. 8(B) shows printed wiring board 30 in FIG. 6. First opening portion (28a) and second opening portion (28b) are connected at connected portion (28c). A line passing through the connected portion and parallel to the first surface of the core substrate (horizontal line PP) is shifted from a line passing through the central location of the metal layer and parallel to the first surface of the core substrate (horizontal line CC). Horizontal line (PP) and horizontal line (CC) do not overlap. Horizontal line (PP) is shifted from horizontal line (CC) by predetermined distance (d). Horizontal line (PP) is closer to the second resin insulation layer than is horizontal line (CC). Intersection (1) is where straight line (L), which is perpendicular to the first surface of the metal layer, intersects the first surface of the metal layer; and intersection (2) is where straight line (L), which is perpendicular to the first surface of the metal layer, intersects the second surface of the metal layer. Horizontal line (CC) is the straight line which passes through the middle point between intersection (1) and intersection (2) and is parallel to the first surface of the core substrate. The central location of the metal layer is positioned on horizontal line (CC).

A printed wiring board according to the embodiment is formed with first opening portion (28a) and second opening portion (28b) which become gradually narrower toward the center of the core substrate. Then, connected portion (28c) of the first opening portion and the second opening portion is shifted from central location (CC) of metal layer 20 toward the main surface of the second resin insulation layer. When a penetrating hole is filled with plating, the plating solution tends to enter the penetrating hole from the first opening portion (28a) side and to exit from the second opening portion (28b) side. Thus, first opening portion (28a) with a greater volume and second opening portion (28b) with a smaller volume are filled with plated film without causing a void. Accordingly, reliability is enhanced in through-hole conductor 36 of the embodiment.

In a printed wiring board of the embodiment, connected portion (28c) is preferred to be shifted from central location (CC) of metal layer 20 by a predetermined distance. When the thickness of the metal layer is set as (D), shifted amount (d) is preferred to be D/2 or less. A through-hole conductor of the embodiment has a bent portion at connected portion (28c) of the first opening portion and the second opening portion, and the bent portion does not correspond to the central location of the metal layer. Therefore, the volume of a through-hole conductor from horizontal line (CC) to the first surface of the core substrate tends to be different from the volume of the through-hole conductor from horizontal line (CC) to the second surface of the core substrate. The greater the difference in the volumes, the more likely it is that the printed wiring board warps. The greater the warping, the greater the stress exerted on the bent portion of the through-hole conductor. Accordingly, shifted amount (d) is preferred to be D/2 or less in a printed wiring board of the embodiment.

On the other hand, shifted amount (d) of connected portion (28c) is preferred to be D/8 or greater. When the temperature rises in a printed wiring board of the embodiment, the connected portion is pressed by the filler resin. To reduce the pressing force, shifted amount (d) is preferred to be D/8 or greater.

In a through-hole conductor of the embodiment, the diameter of the portion that passes through the metal layer is narrow. Thus, the volume of the metal layer increases. Accordingly, a printed wiring board of the embodiment is excellent in heat dissipation. When heat dissipation is excellent, the amount of expansion by heat decreases, and the through-hole conductor is less likely deformed. Accordingly, although a through-hole conductor in the printed wiring board of the embodiment has a narrow portion, cracking seldom occurs in the through-hole conductor. According to a printed wiring board of the embodiment, the diameter of a penetrating hole for a through-hole conductor is set greater at the ends of the penetrating hole, and narrower near the center of the core substrate. Thus, it is easier to fill the penetrating hole with plating, and a void or the like seldom remains in the through-hole conductor. From such a point of view, reliability is also enhanced in a through-hole conductor of the embodiment.

In multilayer printed wiring board 10 of the embodiment, a through-hole conductor tapers from the first surface of the core substrate toward the filler resin, and tapers from the second surface of the core substrate toward the filler resin. Thus, the area of the ends of a through-hole conductor increases. As a result, since it is easy to form via conductor 60 on the through-hole conductor (an end), productivity improves. Also, the connection reliability is enhanced between a through-hole conductor and a via conductor formed directly on the through-hole conductor.

Metal layer 20 of printed wiring board 30 is preferred to be used as power supply or ground. Roughened layers may be formed on metal layer 20. Adhesiveness with first resin insulation layer 24, second resin insulation layer 25 and filler resin 27 improves.

The first resin insulation layer and the second resin insulation layer are preferred to contain reinforcing material (core material). As for the reinforcing material, glass cloth, aramid fiber and the like may be listed. The first resin insulation layer and the second resin insulation layer may contain reinforcing material and inorganic particles such as silica. Filler resin is preferred not to contain reinforcing material such as glass cloth and aramid fiber. Filler resin is preferred not to contain reinforcing material but to contain inorganic particles. When the first resin insulation layer and the second resin insulation layer contain reinforcing material (core material) and inorganic particles, their thermal expansion coefficient is closer to that of the metal layer. When filler resin contains inorganic particles, its thermal expansion coefficient is closer to that of the metal layer. Cracking seldom occurs in the first resin insulation layer, the second resin insulation layer or filler resin during heat cycles. Also, peeling is prevented between the metal layer and the first resin insulation layer, the second resin insulation layer or filler resin during heat cycles.

Filler resin 27 is formed by resin that has flowed from at least either first resin insulation layer 24 or second resin insulation layer 25 into an opening in the metal layer. In such a case, it is preferred that resin and inorganic particles from at least either the first resin insulation layer or the second resin insulation layer flow into an opening in the metal layer.

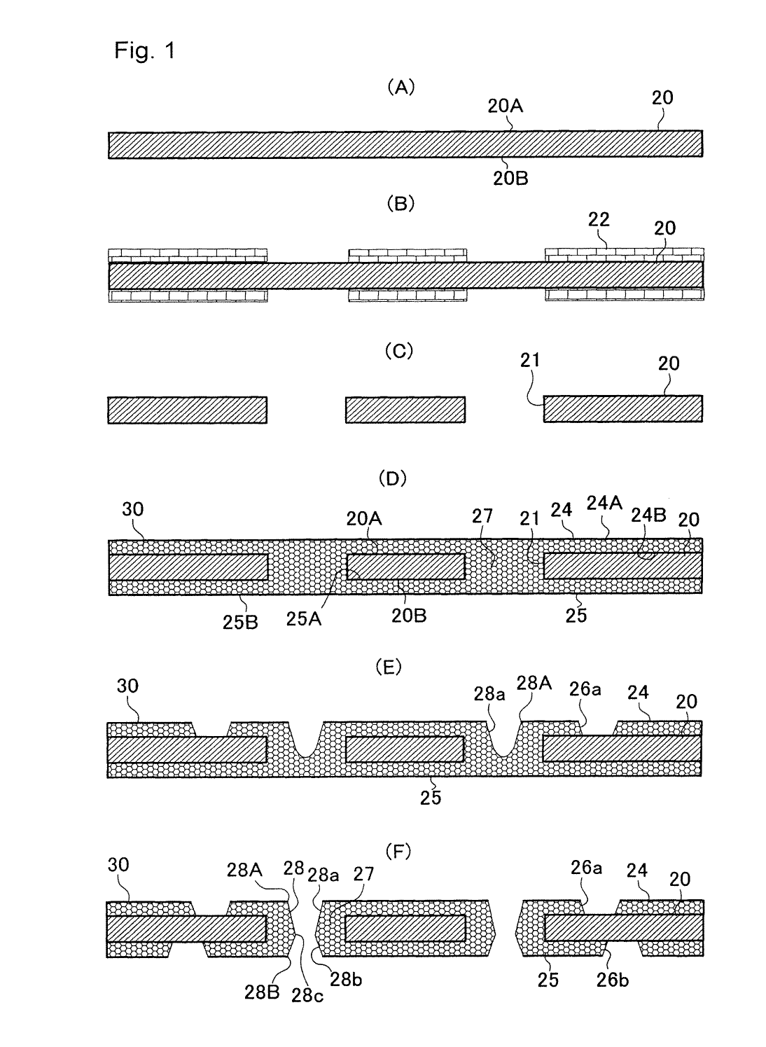

FIGS. 1 through 6 show a method for manufacturing multilayer printed wiring board 10. Metal layer (metal sheet) 20 is prepared (FIG. 1(A)). The thickness of the metal layer is preferred to be from 15 μm to 150 μm. When the thickness of the metal layer is in the above range, heat is radiated through the metal layer, and malfunctions seldom occur in electronic components such as a memory mounted on printed wiring board 30 or on multilayer printed wiring board 10. Also, in printed wiring board 30 and multilayer printed wiring board 10 according to the embodiment, the portion of a through-hole conductor that penetrates through the metal layer is narrow. Although cracking tends to occur in a narrow portion, since the thickness of the metal layer is thin, the narrow portion of a through-hole conductor is short in printed wiring board 30 and multilayer printed wiring board 10 according to the embodiment. As a result, reliability increases in the through-hole conductor. Since printed wiring board 30 and multilayer printed wiring board 10 of the embodiment have excellent heat radiation, the amount of deformation decreases in printed wiring board 30 and multilayer printed wiring board 10. Therefore, even though a through-hole conductor in printed wiring board 30 and multilayer printed wiring board 10 of the embodiment has a narrow portion, malfunctions such as cracking seldom occur in the through-hole conductor.

The metal layer (metal sheet) has first surface (20A) and second surface (20B) opposite the first surface. Metals such as copper, nickel, aluminum, titanium and zinc are listed as the material for metal foil and metal sheet to be used for the metal layer. Alloys of metals selected from those metals are also used as the material. As for specific examples, alloy 42, kovar, bronze and copper foil are listed. Here, the metal sheet may be a single layer or a laminate of multiple metal layers. An example of a laminate is a triple-layer laminate formed with metal foil mainly containing nickel sandwiched by metal foils mainly containing copper. The thickness of each layer and the combination of the materials are not limited specifically. Among those, copper is preferred as a material for the metal layer; copper foil is especially preferred. Since conductive circuits of the printed wiring board are made of metal mainly containing copper, problems related to electrical characteristics seldom occur. Also, when the metal layer is made of copper foil, openings and roughened surfaces are easy to form.

(2) Etching resist 22 is formed on the first and second surfaces of metal layer 20 (FIG. 1(B)). The etching resist on the first surface and the etching resist on the second surface are preferred to have the same pattern. Alternatively, the etching resist may be formed only on either the first surface or the second surface.

(3) A portion of the metal layer exposed from etching resist 22 is removed by etching. Opening 21 is formed in metal layer 20. After that, the etching resist is removed. The metal layer with opening 21 is completed (FIG. 1(C)). The size of opening 21 is 150 μm˜260 μm. The minimum diameter of a penetrating hole for a through-hole conductor divided by the diameter of opening 21 is 0.12˜0.7. Other than etching, a laser or a drill may also be used for forming opening 21. The surfaces of the metal layer may be roughened. The first and second surfaces of the metal layer are roughened. The inner wall of the opening in the metal layer is also preferred to be roughened. The minimum diameter of a penetrating hole for a through-hole conductor is the minimum distance at the neck portion.

(4) Insulation layers are laminated on both surfaces of the metal layer. The insulation layers are preferred to contain a core material and B-stage resin. The core material is glass cloth, aramid fiber or the like. Resin is epoxy, polyimide or the like. In addition, insulation layers are preferred to contain inorganic particles. Inorganic particles are silica, alumina or the like. The thickness of the insulation layers is 20 μm to 200 μm. The metal layer and insulation layers sandwiching the metal layer are thermal pressed. The metal layer and the insulation layers are integrated. During that time, resin contained in the insulation layers seeps into the opening in the metal layer and fills the opening in the metal layer with the resin contained in the insulation layers. If the insulation layers contain inorganic particles, resin and inorganic particles contained in the insulation layers seep into the opening in the metal layer. Opening 21 in the metal layer is filled with resin and inorganic particles contained in the insulation layers. Then, resin in the insulation layers and resin in the opening are cured. Filler resin 27 is formed in opening 21. Filler resin is preferred to be formed with resin and inorganic particles. In addition, on the first surface of the metal layer, a first resin insulation layer having an upper surface and a lower surface opposite the upper surface is formed. The first surface of the metal layer faces the lower surface of the first resin insulation layer. On the second surface of the metal layer, a second resin insulation layer having a main surface and a secondary surface opposite the main surface is formed. The second surface of the metal layer faces the secondary surface of the second resin insulation layer (FIG. 1(D)).

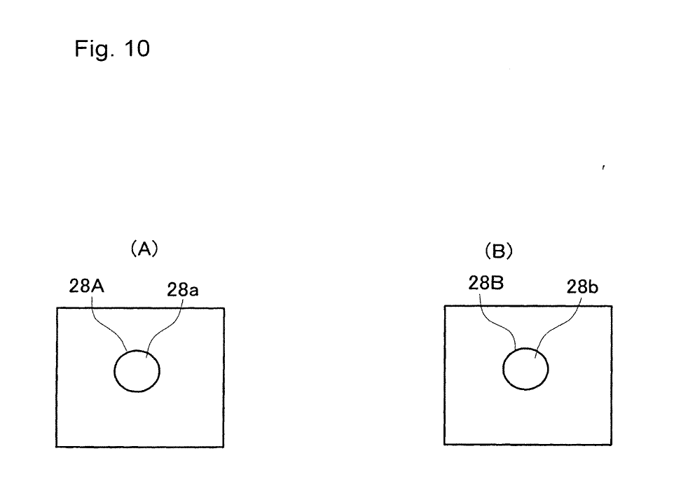

(5) A laser is irradiated from the upper-surface side of the first resin insulation layer. First opening portion (28a) is formed in the first resin insulation layer as part of a penetrating hole for a through-hole conductor. Moreover, via-conductor opening (26a) reaching the metal layer is formed in the first resin insulation layer (FIG. 1(E)). Here, first opening portion (28a) has first opening (28A) on the upper surface of the first resin insulation layer, and tapers from the upper surface toward the lower surface. The first opening portion becomes narrower from the upper surface of the first resin insulation layer toward the lower surface. By using a laser having intense energy in the center, a taper-shaped first opening portion is formed. FIG. 10(A) shows the upper surface of the first resin insulation layer, and the first opening portion has first opening (28A) on the upper surface.

(6) A laser is irradiated from the main-surface side of the second resin insulation layer. Second opening portion (28b) is formed in the second resin insulation layer as part of a penetrating hole for a through-hole conductor. Penetrating hole 28 is completed. FIG. 10(B) shows the main surface of the second resin insulation layer, and the second opening portion has second opening (28B) on the main surface. Via-conductor opening (26b) reaching the metal layer is further formed in the second resin insulation layer (FIG. 1(F)). Second opening portion (28b) has second opening (28B) on the main surface of the second resin insulation layer, and tapers from the main surface toward the secondary surface. The second opening portion becomes narrower from the main surface of the second resin insulation layer toward the secondary surface. By using a laser having intense energy in the center, a taper-shaped second opening portion is formed. A magnified view of FIG. 1(F) is shown in FIG. 8(A). As shown in FIGS. 6 and 8(B), connected portion (28c) of the first opening portion and the second opening portion is shifted by distance (d) from central location (CC) of metal layer 20 toward the main-surface side of the second resin insulation layer. By modifying the laser intensity or by changing the number of irradiations for forming the first opening portion and the second opening portion, the connected portion is shifted. By modifying the laser conditions for the first opening portion and the second opening portion, shifted amount (d) is controlled to be in the range of D/8 to D/2.

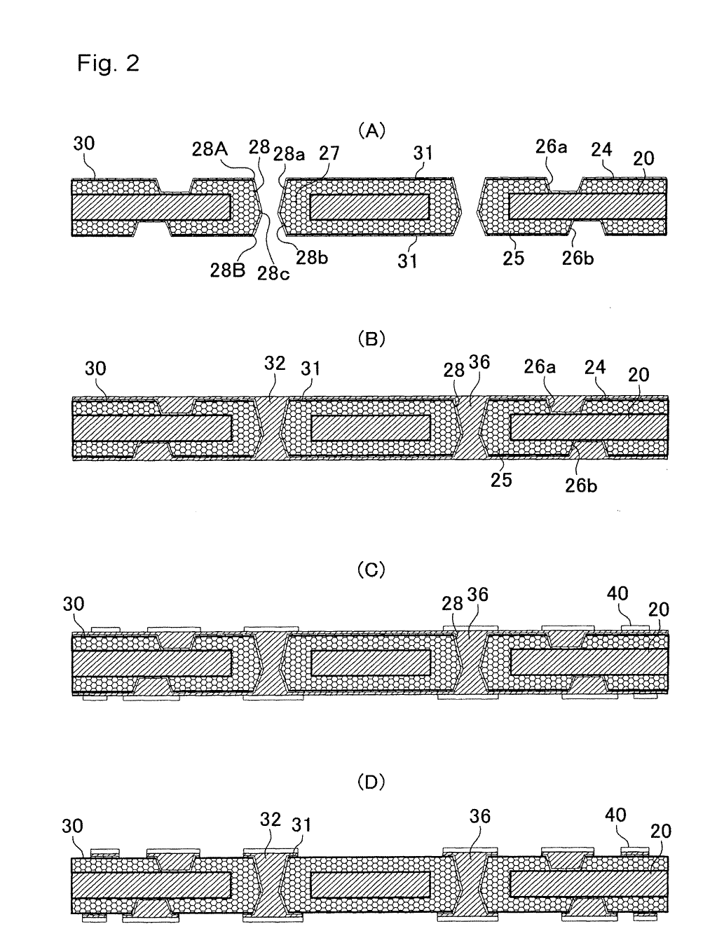

(7) Seed layer 31 is formed on the inner wall of a penetrating hole, the surface of the first resin insulation layer and the surface of the second resin insulation layer (FIG. 2(A)). The seed layer is electroless plated film or sputtered film. As for a seed layer, copper is preferred.

(8) Using seed layer 31 as an electrode, electrolytic plating is performed. Electrolytic plated film 32 is formed on the seed layer. The penetrating hole is filled with electrolytic plated film. Through-hole conductor 36, which is made of a seed layer and electrolytic plated film 32 on the seed layer, is formed. When a resin insulation layer has a via-conductor opening, the via-conductor opening is filled with electrolytic plated film (FIG. 2(B)).

(9) Etching resist 40 with a predetermined pattern is formed on electrolytic plated film 32 on the substrate surfaces (FIG. 2(C)).

(10) Seed layer 31 and electrolytic plated film 32 exposed from etching resist 40 are removed (FIG. 2(D)).

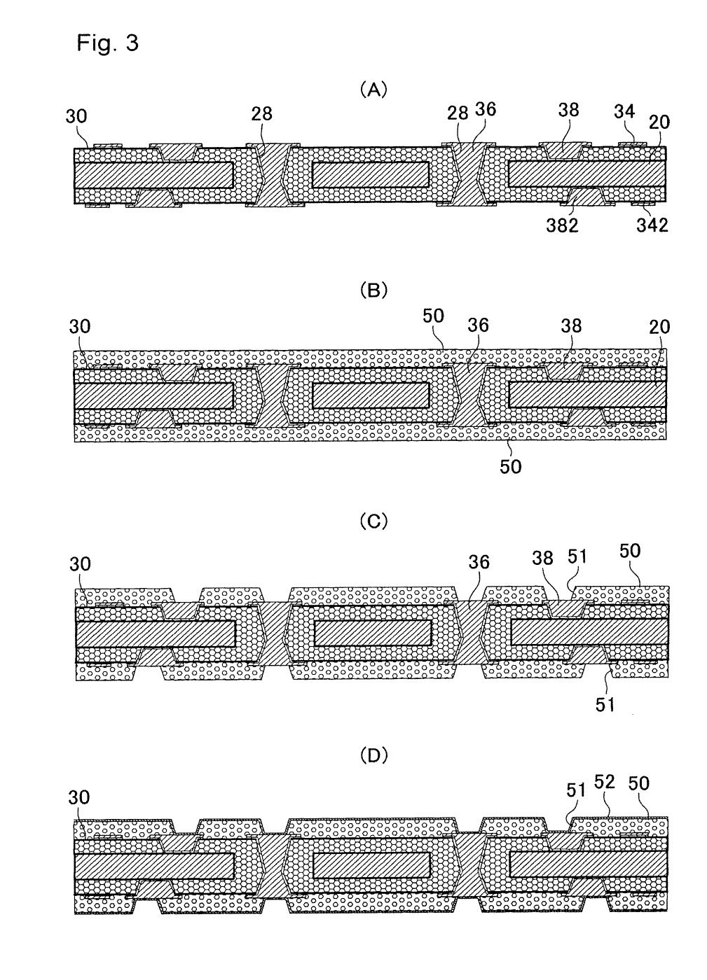

(11) Etching resist 40 is removed. Conductive circuit 34 is formed on the upper surface of the first resin insulation layer. Conductive circuit 342 is formed on the main surface of the second resin insulation layer. Conductive circuit 34 and conductive circuit 342 are connected by through-hole conductor 36. When the resin insulation layers have via-conductor openings, via conductors (38, 382) are formed in their respective openings. Via conductors connect the metal layer and conductive circuits (34, 342). When resin insulation layers have via conductors, the metal layer is preferred to function as ground or power supply. Printed wiring board 30 is completed (FIG. 3(A)). The core substrate is formed with a metal layer, a first resin insulation layer, a second resin insulation layer, filler resin and a through-hole conductor. The core substrate has a first surface and a second surface opposite the first surface. The first surface of the core substrate and the upper surface of the first resin insulation layer are on the same plane, and the second surface of the core substrate and the main surface of the second resin insulation layer are on the same plane. FIG. 8(B) is a magnified view of the core substrate. In the embodiment, the diameter of penetrating hole 28 for a through-hole conductor is set greater at first opening (28A) and second opening (28B) (end portions), and narrow at connected portion (28c). Therefore, since plating starts filling the penetrating hole at connected portion (28c), a void seldom remains in the through-hole conductor. Moreover, connected portion (28c) of first opening portion (28a) and second opening portion (28b) is shifted by distance (d) from central location (CC) of metal layer 20 toward the main-surface side of the second resin insulation layer.

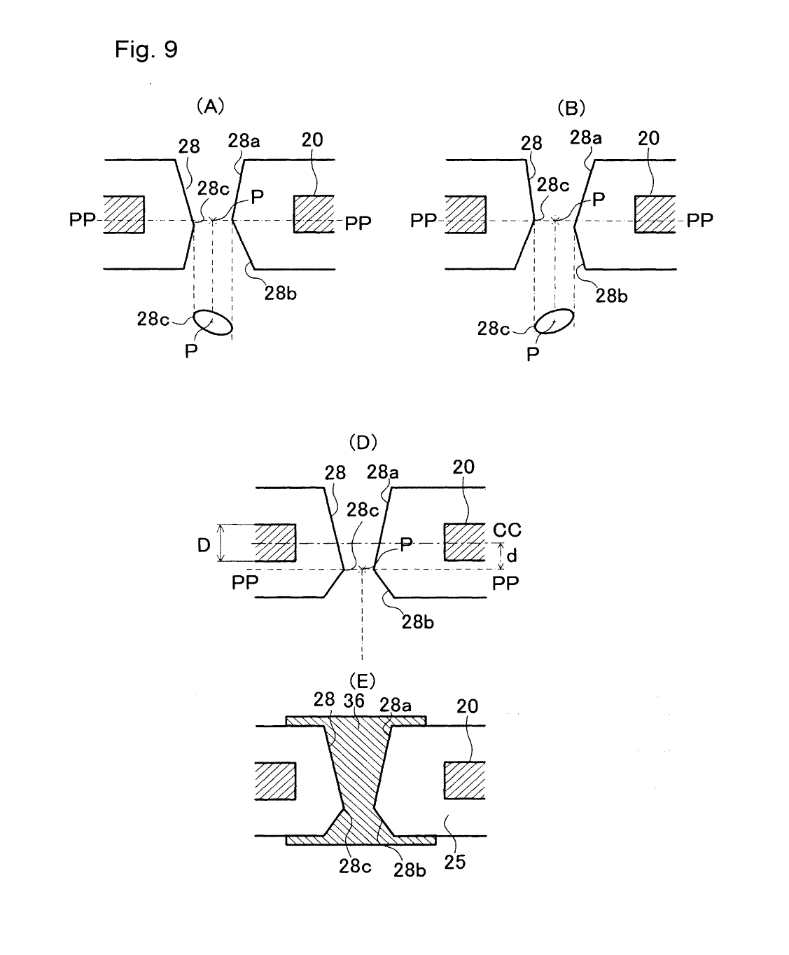

The line obtained by connecting the dots where the wall of first opening portion (28a) intersects the wall of second opening portion (28b) is referred to as a line of intersection of first opening portion (28a) and second opening portion (28b). In the present application, the line of intersection corresponds to the line of intersection where first opening portion (28a) intersects second opening portion (28b). Then, the region surrounded by the line of intersection is referred to as the neck portion. In FIGS. 6, 7 and 8, the line of intersection and the neck portion are parallel to the first surface of the core substrate. FIGS. 9(A) and 9(B) show examples in which the line of intersection and the neck portion are not parallel to the first surface of the core substrate, and the neck portion is elliptical. By shifting the positions for forming first opening portion (28a) and second opening portion (28b), lines of intersection and neck portions such as shown in FIGS. 9(A) and 9(B) are formed. In such examples, the connected portion corresponds to gravity center (P) of the neck portion. Distance (d) between plane (PP), which includes gravity center (P) and is parallel to the first surface of the core substrate, and plane (CC) in the center of the metal layer corresponds to the shifted amount.

FIG. 9(D) shows an example in which connected portion (28c) is present in the second resin insulation layer. First opening portion (28a) and second opening portion (28b) are connected in the second resin insulation layer. Shifted amount (d) exceeds D/2. FIG. 9(E) shows through-hole conductor 36 obtained by filling penetrating hole 28 in FIG. 9(D) with plating film. The through-hole conductor shown in FIG. 9(E) is included in the embodiment of the present invention. However, the connected portion of the through-hole conductor shown in FIG. 9(E) is not surrounded by a metal layer. Therefore, compared with the example in which the connected portion is surrounded by a metal layer (FIGS. 6, 7, 8), the connected portion of the through-hole conductor shown in FIG. 9(E) receives more of the force generated due to warping in the printed wiring board. Accordingly, the through-hole conductor shown in FIG. 9(E) has lower reliability than through-hole conductors shown in FIGS. 6, 7, 8, 9(A) and 9(B).

The thermal expansion coefficient of resin is generally greater than the thermal expansion coefficient of metal. Also, a through-hole conductor is usually surrounded by resin. Therefore, when the temperature of a printed wiring board rises, it is thought that a through-hole conductor is pressed by resin. A through-hole conductor of the embodiment is bent at the connected portion of a first opening portion and a second opening portion. The through-hole conductor of the embodiment has a bent portion at the connected portion of the first opening portion and the second opening portion. Accordingly, when the temperature rises, it is thought that the through-hole conductor of the embodiment is more susceptible to damage than a through-hole conductor in a straight shape, because the force tends to concentrate at the bent portion. To reduce the force to be exerted on the bent portion, the printed wiring board of the embodiment has a metal layer. In the embodiment, a rise in temperature in the printed wiring board is suppressed because of the metal layer. Furthermore, the connected portion of the first opening portion and the second opening portion is shifted from the central location of the metal layer (the center) in the embodiment. Here, the central location of the metal layer is on horizontal line (CC). Since the center is farthest from the first surface and the second surface of the metal layer, the temperature in the center is thought to be higher than the temperatures elsewhere. Resin is thought to expand more in the central location of the metal layer than in the other locations. Thus, if the position of the connected portion corresponds to the central location of the metal layer, it is thought that reliability decreases in a through-hole conductor of the embodiment. That is because if the connected portion is positioned in the center, it is thought that force is exerted more on the connected portion than otherwise. Accordingly, the position of the connected portion is shifted from the central location of the metal layer in the embodiment. By shifting the position of the connected portion from the central location of the metal layer, it is thought that the force to be exerted on the connected portion is reduced. A through-hole conductor has a bent portion in the embodiment; however, a printed wiring board of the embodiment has a metal layer while the position of the connected portion is shifted from the central location of the metal layer. Accordingly, the reliability of a through-hole conductor is high in a printed wiring board of the embodiment.

### MODIFIED EXAMPLE OF EMBODIMENT

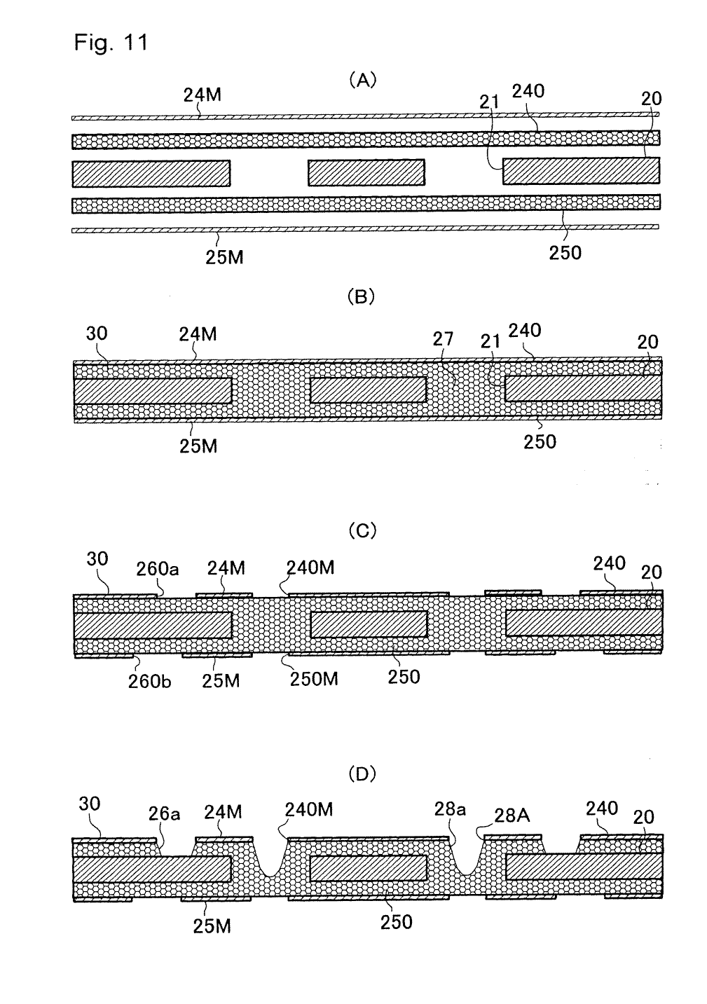

In a modified example of the embodiment, metal foil is further laminated on the insulation layers in step (b 4) of the embodiment (FIG. 11(A)). As for the metal foil, 3 μm to 15 μm copper foil is preferred. Metal layer 20, insulation layers (240, 250) sandwiching the metal layer, metal foil (24M) on insulation layer 240 and metal foil (25M) on insulation layer 250 are integrated through thermal pressing (FIG. 11(B)). By curing insulation layers (240, 250), first and second resin insulation layers are formed on the metal layer. Also, the same as in the embodiment, filler resin is formed in opening 21 of the metal layer. Openings (240M, 250M) are formed in metal foils (24M, 25M) in portions positioned on filler resin 27 (FIG. 11(C)).

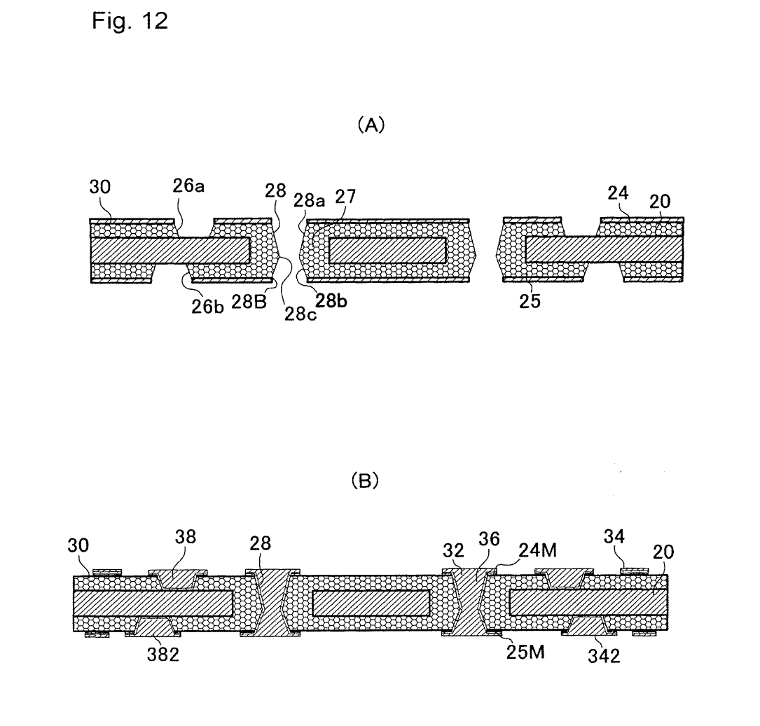

Next, a laser is irradiated at first resin insulation layer 24 through opening (240M) in the metal foil, and first opening portion (28a) is formed in the first resin insulation layer (FIG. 11(D)). A laser is irradiated at second resin insulation layer 25 through opening (250M) in the metal foil, and second opening portion (28b) is formed in the second resin insulation layer (FIG. 12(A)). The same as in the embodiment, connected portion (28c) of first opening portion (28a) and second opening portion (28b) is shifted from the center of the metal layer toward the second resin insulation layer.

Conductive circuits (34, 342) and a through-hole conductor are formed in substantially the same manner as those in the embodiment. In the modified example of the embodiment, the seed layer, electrolytic plated film and metal foils (24M, 25M) exposed from the etching resist are removed when conductive circuits are formed. Printed wiring board 30 is completed (FIG. 12(B)).

In the modified example of the embodiment, conductive circuits (34, 342) are formed with metal foil, a seed layer on the metal foil and electrolytic plated film on the seed layer; and a through-hole conductor is formed with a seed layer and electrolytic plated film on the seed layer. The through-hole land formed around the through-hole conductor is formed with metal foil, a seed layer on the metal foil and electrolytic plated film on the seed layer.

### Forming Buildup Layers

Interlayer resin insulation layers (brand name: ABF-45SH made by Ajinomoto) 50 are formed on both surfaces of printed wiring board 30 (see FIG. 3(B)).

Next, using a CO2 gas laser, via-conductor openings 51 with a diameter of 40 μm˜80 μm are formed in interlayer resin insulation layers 50 (see FIG. 3(C)).

Electroless plated film 52 is formed on the surface layers of interlayer resin insulation layers 50 and on the inner walls of via-conductor openings (FIG. 3(D)).

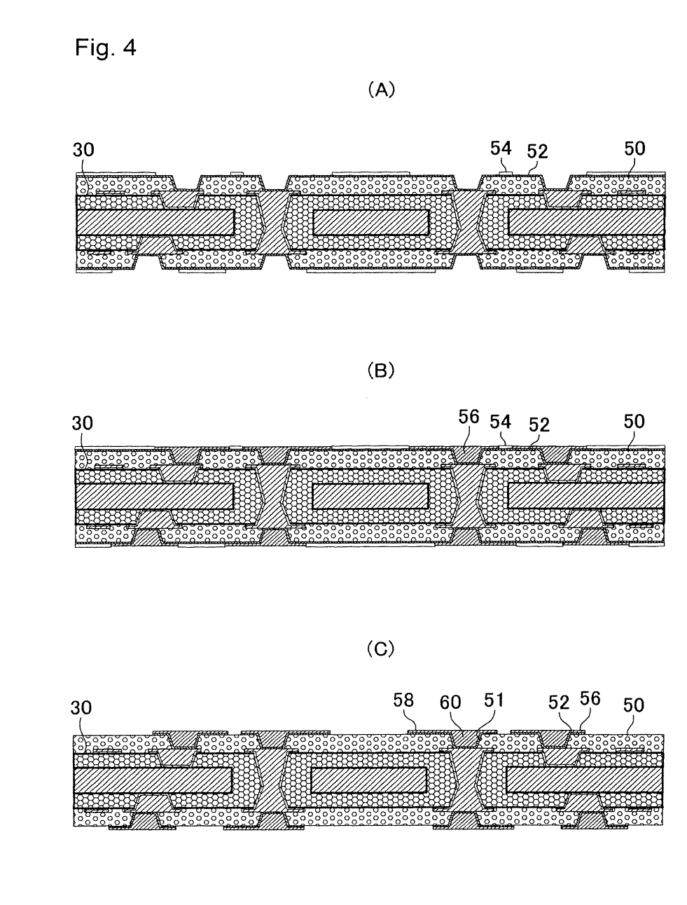

Plating resist 54 is formed on electroless plated film 52 (FIG. 4(A)).

Next, electrolytic plated film 56 is formed on the electroless plated film (see FIG. 4(B)).

Plating resist 54 is removed. Then, electroless plated film 52 between portions of electrolytic plated film 56 is removed. Conductive circuits 58 and via conductors 60 made up of electroless plated film 52 and electrolytic plated film 56 are formed (FIG. 4(C)).

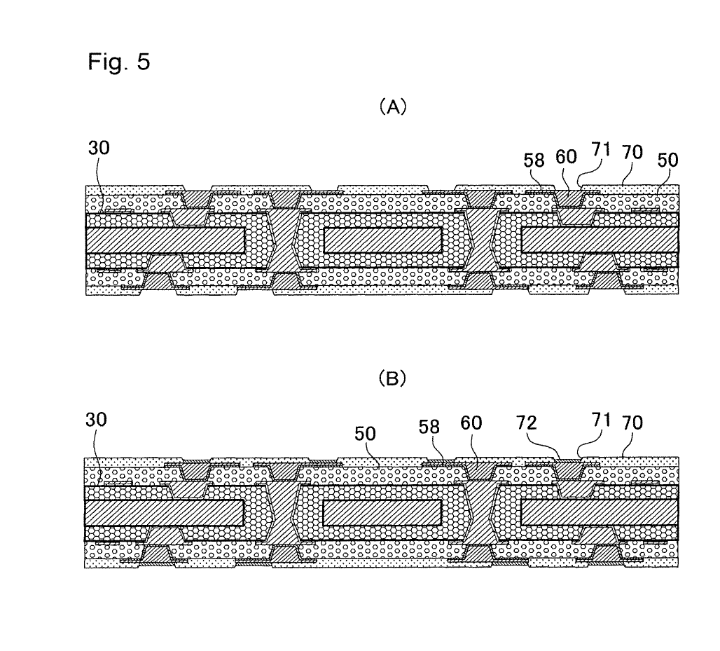

Next, interlayer resin insulation layers, conductive circuits and solder-resist layers 70 having openings 71 on via conductors are formed (FIG. 5(A)). Conductive portions exposed through the openings in the solder resist function as pads.

Sn film 72 is formed on the pads (FIG. 5(B)).

Then, by loading solder balls in openings 71 and conducting a reflow, solder bumps (76U, 76D) are formed on the pads. Multilayer printed wiring board 10 is completed (FIG. 6).

IC chip 90 is mounted through solder bumps (76U) on multilayer printed wiring board 10 (FIG. 7).

### EXAMPLE

(1) A 35 μm copper foil 20 is prepared (FIG. 1(A)). The copper foil has a first surface and a second surface opposite the first surface.

(2) Etching resists 22 having the same pattern are formed on the first surface and second surface of copper foil 20 (FIG. 1(B)).

(3) The copper foil exposed from etching resists 22 is removed by etching. Opening 21 is formed in copper foil 20. Then, the etching resists are removed. A metal layer having opening 21 is completed (FIG. 1(C)). The size of opening 21 is 150 μm (FIG. 8(A)). The first surface and the second surface of the copper foil and the inner wall of opening 21 are roughened by a Cz treatment (made by Mec Company Ltd.).

(4) Commercially available prepreg sheets (60 μm) (240, 250) are laminated on both surfaces of the metal layer. The prepreg contains silica particles and glass cloth (FIG. 11(A)).

(5) On the outer side of the prepreg sheets, 5 μm copper foils (24M, 25M) are laminated (FIG. 11(A)).

(6) Copper foil 20, prepreg sheets (240, 250) sandwiching the copper foil, and copper foils (24M, 25M) on the outer side of the prepreg sheets are integrated through thermal pressing. During that time, resin and silica particles contained in the prepreg fill opening portion 21 in copper foil 20. Then, by curing the resin of the prepreg and the resin inside opening 21, first resin insulation layer 24, second resin insulation layer 25 and filler resin 27 are formed (FIG. 11(B)).

(7) Openings (240M, 250M) are formed in copper foils (24M, 25M) (FIG. 11(C)). Openings (240M, 250M) are formed in positions facing the filler resin. Openings (260a, 260b) are formed in copper foils in positions to form via-conductor openings. The diameters of openings (240M, 250M) are 80 μm (FIG. 8(A)). Copper foils (24M, 25M) are not shown in FIG. 8.

(8) A CO2 laser is irradiated at the first resin insulation layer through opening (240M) in copper foil (24M) from the upper-surface side of the first resin insulation layer. First opening portion (28a) is formed in the first resin insulation layer as part of a penetrating hole for a through-hole conductor (FIG. 11(D)). The energy of the laser for forming first opening portion (28a) is stronger in the center than in the periphery. Therefore, first opening portion (28a) becomes gradually narrower from the upper surface of the first resin insulation layer toward the lower surface. First opening portion (28a) has first opening (28A) on the upper surface of the first resin insulation layer. The diameter of the first opening is 80 μm (FIG. 8(A)). Via-conductor opening (26a) reaching the metal layer is formed in first resin insulation layer 240. The top diameter of the via-conductor opening is 70 μm and the bottom diameter is 50 μm (FIG. 8(A)).

(9) A CO2 laser is irradiated at the second resin insulation layer through opening (250M) in copper foil (25M) from the main-surface side of the second resin insulation layer. Second opening portion (28b) is formed in the second resin insulation layer as part of a penetrating hole for a through-hole conductor (FIG. 12(A)). The energy of the laser for forming second opening portion (28b) is stronger in the center than in the periphery. Therefore, second opening portion (28b) becomes gradually narrower from the main surface of the second resin insulation layer toward the secondary surface. In addition, (the laser intensity for forming the second opening portion)/(the laser intensity for forming the first opening portion) is approximately 4/5. Therefore, connected portion (28c) of first opening portion (28a) and second opening portion (28b) is shifted by 7 μm from the center of the metal layer toward the second resin insulation layer. Second opening portion (28b) has second opening (28B) on the main surface of the second resin insulation layer. The diameter of the second opening is 80 μm. The minimum diameter of the penetrating hole for a through-hole conductor is 60 μm (FIG. 8). A via-conductor opening reaching the metal layer is formed in the second resin insulation layer. The top diameter of the via-conductor opening is 70 μm and the bottom diameter is 50 μm (FIG. 8(A)).

(10) Using a commercially available electroless copper plating solution, electroless copper-plated film 31 is formed on the inner wall of the penetrating hole, on the copper foil formed on the first resin insulation layer, on the copper foil formed on the second resin insulation layer, on the inner wall of the via-conductor opening in the first resin insulation layer, and on the inner wall of the via-conductor opening in the second resin insulation layer (FIG. 2(A)).

(11) Electrolytic copper-plated film 32 is formed on electroless copper-plated film 31 using a commercially available electrolytic copper plating solution. The penetrating hole is filled with the electrolytic copper plated film, and through-hole conductor 36, which is made up of electroless copper-plated film and of electrolytic copper plated film 32 on the electroless copper-plated film, is formed in penetrating hole 28. Also, via-conductor opening (26a) formed in the resin insulation layer is filled with electrolytic plated film.

(12) Etching resist 40 with a predetermined pattern is formed on electrolytic plated film 32 on the substrate surfaces (FIG. 2(C)).

(13) Electrolytic copper-plated film 32, electroless copper-plated film 31 and copper foil which are exposed from etching resist 40 are removed (FIG. 2(D)).

(14) The etching resist is removed. Conductive circuit 34 is formed on the upper surface of the first resin insulation layer, and conductive circuit 342 is formed on the main surface of the second resin insulation layer. Conductive circuit 34 and conductive circuit 342 are connected by through-hole conductor 36. Via conductors (38, 382) are formed in via-conductor openings in the resin insulation layers. Via conductors connect the metal layer and conductive circuits (34, 342). The metal layer works as ground. Printed wiring board 30 is completed (FIG. 12(B)).

(15) Interlayer resin insulation layers (brand name ABF-45SH, made by Ajinomoto) 50 are formed on both surfaces of printed wiring board 30 (see FIG. 3(B)).

(16) Next, via-conductor openings 51 with a diameter of 60 μm are formed in interlayer resin insulation layers 50 using a CO2 gas laser (see FIG. 3(C)).

(17) Using a commercially available electroless copper plating solution, electroless copper-plated film 52 is formed on the surface layers of interlayer resin insulation layers 50 and on the inner walls of via-conductor openings (FIG. 3(D)).

(18) Commercially available plating resist 54 is formed on electroless copper-plated film 52 (FIG. 4(A)).

(19) Next, electrolytic copper-plated film 56 is formed on the electroless plated film (FIG. 4(B)).

(20) Plating resist 54 is removed. Then, electroless plated film 52 between portions of electrolytic copper-plated film 56 is removed. Conductive circuits 58 and via conductors 60 made up of electroless plated film 52 and electrolytic plated film 56 are formed (FIG. 4(C)).

(21) Interlayer resin insulation layers, conductive circuits and solder-resist layers 70 having openings 71 on via conductors are formed (FIG. 5(A)). The conductive portions exposed through the solder-resist openings function as pads. The solder-resist layers are formed using commercially available material.

(22) Sn film 72 is formed on the pads (FIG. 5(B)).

(23) Then, by loading solder balls in openings 71 and conducting a reflow, solder bumps (76U, 76D) are formed on the first surface of the pads (upper surface). Multilayer printed wiring board 10 is completed (FIG. 6).

A printed wiring board according to one aspect of the present invention includes the following: a metal layer with an opening and having a first surface and a second surface; a filler resin filled in the opening of the metal layer; a first resin insulation layer having an upper surface and a lower surface, and formed on the first surface of the metal layer in such a way that the lower surface faces the first surface of the metal layer; a second resin insulation layer having a main surface and a secondary surface, and formed on the second surface of the metal layer in such a way that the secondary surface faces the second surface of the metal layer; a first conductive circuit formed on the upper surface of the first resin insulation layer; a second conductive circuit formed on the main surface of the second resin insulation layer; and a through-hole conductor which is formed in a penetrating hole that penetrates through the first resin insulation layer, the filler resin and the second resin insulation layer and which connects the first conductive circuit and the second conductive circuit. Then, the penetrating hole is made up of a first opening portion which is formed in the first resin insulation layer and becomes gradually narrower from the upper surface of the first resin insulation layer toward the filler resin, and of a second opening portion which is formed in the second resin insulation layer and becomes gradually narrower from the main surface of the second resin insulation layer toward the filler resin, and a connected position of the first opening portion and the second opening portion is shifted from the central location of the metal layer in a thickness direction toward the main-surface side of the second resin insulation layer.

A method for manufacturing a printed wiring board according to another aspect of the present invention includes the following: preparing a metal layer having a first surface and a second surface opposite the first surface; forming an opening in the metal layer; on the first surface of the metal layer, forming a first resin insulation layer having an upper surface and a lower surface opposite the upper surface in such a way that the lower surface faces the first surface of the metal layer; on the second surface of the metal layer, forming a second resin insulation layer having a main surface and a secondary surface opposite the main surface in such a way that the secondary surface faces the second surface of the metal layer; filling the opening of the metal layer with filler resin; forming a penetrating hole that penetrates through the first resin insulation layer, the filler resin and the second resin insulation layer; forming a first conductive circuit on the upper surface of the first resin insulation layer; forming a second conductive circuit on the main surface of the second resin insulation layer; and in the penetrating hole, forming a through-hole conductor which connects the first conductive circuit and the second conductive circuit. Then, forming the penetrating hole includes forming a first opening portion in the first resin insulation layer to become gradually narrower from the upper surface of the first resin insulation layer toward the filler resin, as well as forming a second opening portion in the second resin insulation layer to become gradually narrower from the main surface of the second resin insulation layer toward the filler resin and to be connected to the first opening portion, and the second opening portion is formed in such a way that the connected portion of the first opening portion and the second opening portion is shifted a predetermined distance from the central location of the metal layer in a thickness direction.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a metal layer having an opening portion;
a resin structure comprising a first resin layer portion formed on a first surface of the metal layer, a second resin layer portion formed on a second surface of the metal layer on an opposite side of the first surface, and a filler resin portion filling the opening portion of the metal layer;
a first conductive circuit formed on the first resin insulation layer portion;
a second conductive circuit formed on the second resin insulation layer portion; and
a through-hole conductor formed through the first resin insulation layer portion, the filler resin portion and the second resin insulation layer portion and connecting the first conductive circuit and the second conductive circuit,
wherein the through-hole conductor has a first portion narrowing from the first conductive circuit toward the second resin insulation layer portion and a second portion narrowing from the second conductive circuit toward the first resin insulation layer portion, and the first portion of the through-hole conductor is connected to the second portion of the through-hole conductor at a connected position shifted from a middle point of a thickness of the metal layer.

2. The printed wiring board according to claim 1, wherein the connected position of the first portion and second portion of the through-hole conductor is in the filler resin.

3. The printed wiring board according to claim 1, wherein the connected position of the first portion and second portion of the through-hole conductor is in the second resin insulation layer.

4. The printed wiring board according to claim 2, wherein the connected position and the thickness of the metal layer satisfy d=D/8 or greater and D/2 or less, where D represents the thickness of the metal layer, and d represents a shifted distance of the connected position with respect to the middle point of the thickness of the metal layer.

5. The printed wiring board according to claim 1, wherein the first resin insulation layer portion has a thickness which is equal to a thickness of the second resin insulation layer portion.

6. The printed wiring board according to claim 1, further comprising an IC chip mounted on a first conductive circuit side.

7. The printed wiring board according to claim 1, wherein the metal layer has a thickness which is set from 15 μm to 150 μm.

8. The printed wiring board according to claim 1, wherein at least one of the first surface and second surface of the metal layer has a roughened surface.

9. The printed wiring board according to claim 1, wherein at least one of the first resin insulation layer portion and the second resin insulation layer portion includes inorganic particles and a core material.

10. The printed wiring board according to claim 1, further comprising:
a first via conductor formed in the first resin insulation layer portion and extending to the first surface of the metal layer; and
a second via conductor formed in the second resin insulation layer portion and extending to the second surface of the metal layer,
wherein the metal layer is one of a power supply conductor layer and a ground conductor layer.

11. A method for manufacturing a printed wiring board, comprising:
forming an opening through a metal layer;
forming on a first surface of the metal layer a first resin insulation layer;
forming on a second surface of the metal layer on an opposite side of the first surface a second resin insulation layer;
forming a penetrating hole penetrating through the opening of the metal layer such that the penetrating hole penetrates through the first resin insulation layer and the second resin insulation layer;
forming a first conductive circuit on the first resin insulation layer;
forming a second conductive circuit on the second resin insulation layer; and
forming in the penetrating hole a through-hole conductor connecting the first conductive circuit and the second conductive circuit,
wherein the opening of the metal layer is filled with a filler resin derived from at least one of the first resin insulation layer and the second resin insulation layer, the forming of the penetrating hole includes forming a first opening portion in the first resin insulation layer such that the first opening portion is narrowing toward the second resin insulation layer and forming a second opening portion in the second resin insulation layer such that the second opening portion is narrowing toward the first resin insulation layer, connected to the first opening portion and forms a connected portion of the first and second opening portions shifted from a middle point of a thickness of the metal layer.

12. The method for manufacturing a printed wiring board according to claim 11, wherein the forming the second opening portion comprises forming the connected portion of the first opening portion and second opening portion of the penetrating hole in the filler resin.

13. The method for manufacturing a printed wiring board according to claim 11, wherein the forming of the second opening portion comprises forming the connected portion of the first opening portion and second opening portion of the penetrating hole in the second resin insulation layer.

14. The method for manufacturing a printed wiring board according to claim 12, wherein the forming of the second opening portion comprises forming the connected portion such that the connected portion and the thickness of the metal layer satisfy d=D/8 or greater and D/2 or less, where D represents the thickness of the metal layer, and d represents a shifted distance of the connected portion with respect to the middle point of the thickness of the metal layer.

15. The method for manufacturing a printed wiring board according to claim 11, wherein the forming of the first resin insulation layer and the forming of the second resin insulation layer comprise setting thicknesses of the first resin insulation layer and second resin insulation layer to be equal.

16. The method for manufacturing a printed wiring board according to claim 11, further comprising mounting an IC chip on a first conductive circuit side.

17. The method for manufacturing a printed wiring board according to claim 11, wherein the metal layer has a thickness which is set from 15 μm to 150 μm.

18. The method for manufacturing a printed wiring board according to claim 11, further comprising roughening at least one of the first surface and second surface of the metal layer.

19. The method for manufacturing a printed wiring board according to claim 11, wherein at least one of the forming of the first resin insulation layer and the forming of the second resin insulation layer includes incorporating inorganic particles and a core material.

20. The method for manufacturing a printed wiring board according to claim 11, further comprising:
forming in the first resin insulation layer a first via conductor extending to the first surface of the metal layer; and
forming in the second resin insulation layer a second via conductor extending to the second surface of the metal layer,
wherein the metal layer is one of a power supply conductor layer and a ground conductor layer.
